(19) United States
(12) Patent Application Publication
(10) Pub. No.: US 2014/0209957 A1
(43) Pub. Date: Jul. 31, 2014

(54) LIGHT-EMITTING ELEMENT AND MANUFACTURING METHOD THEREOF

(71) Applicant: Delta Electronics, Inc., Taoyuan County (TW)

(72) Inventors: Li-Fan LIN, Taoyuan County (TW); Wen-Chia LIAO, Taoyuan County (TW); Ching-Chuan SHIUE, Taoyuan County (TW); Shih-Peng CHEN, Taoyuan County (TW)

(73) Assignee: Delta Electronics, Inc., Taoyuan County (TW)

(21) Appl. No.: 14/166,302

(22) Filed: Jan. 28, 2014

(30) Foreign Application Priority Data
Jan. 29, 2013 (TW) 102103261

(51) Int. Cl. H01L 33/62; H01L 33/64; H01L 33/52

(52) U.S. Cl. CPC H01L 33/62; H01L 33/52; H01L 33/64
USPC 257/99; 438/26

(57) ABSTRACT

A light-emitting element includes two electrically conductive layers, a flexible insulating layer, a light-emitting chip and an encapsulating body. A groove is formed between the electrically conductive layers. The flexible insulating layer is disposed within the groove and links the electrically conductive layers. The light-emitting chip is placed on one of the electrically conductive layers or crossing over the flexible insulating layer. The light-emitting chip is electrically connected to the electrically conductive layers and covered by the encapsulating body.

### BACKGROUND OF THE INVENTION

1. Field of the Invention

The present invention is related to a light-emitting element and a manufacturing method for the light-emitting element, and in particular to a light emitting diode (LED) and a manufacturing method for the LED.

2. Description of Related Art

Reference is made to FIG. 1A, which is a sectional view of a conventional light-emitting element. The light-emitting element includes a ceramic base 90, a first metal layer 92, a second layer 94, and a light-emitting chip 96. The ceramic base 90 has a plurality of through-holes 900, and an electrically conductive layer 902 is disposed within the through-holes 900. The first metal later 92 is disposed on an upper surface of the ceramic layer 90. The first metal layer 92 includes a chip-mounting section 920 and electrically conductive sections 922 located at two sides of the chip-mounting section 920. The second metal layer 94 is disposed on a lower surface of the ceramic layer 90, and is electrically connected to the electrically conductive sections 922 of the first metal layer 92 via the electrically conductive layer 902. The light-emitting chip 96 is mounted on the chip-mounting section 920 and electrically connected to the electrically conductive sections 922 via a plurality of soldering wires 98. The second metal layer 94 is electrically connected to an external power source for conducting a power source to the electrically conductive sections 922 via the electrically conductive layer 902, and then the power source is conducted to the light-emitting chip 96 via the soldering wires 98 connected to the electrically conductive sections 922 to light the light-emitting chip 96. Therefore, the electrically conductive layer 902 disposed within the through-holes 900 is an indispensable component for electrically connecting the first metal layer 92 and the second metal layer 94.

However, the ceramic base 90 is an expensive and brittle material without flexibility. Therefore, the ceramic base 90 is readily cracked when the thickness is smaller than 300 micrometers. Moreover, the tool consumption is high when cutting the ceramic base 90, and manufacturing cost is also increased. Moreover the thermal coefficient (K value) of the ceramic base 90 is low such that the thermal resistance of a 45 mil light-emitting element with ceramic base 90 is larger than 7° C./W.

Furthermore, in order to prevent the ceramic base 90 from cracking when forming the through-holes 900, the area for forming the through-holes 900 by laser perforation must be smaller than the area of the ceramic base 90 by 20%, which increases manufacturing cost and complexity. Besides, since the electrically conductive layer 92 must be filled in the through-holes 900, if the aperture of each through-hole 900 is too large, it will increase the difficulty of the filling hole or cannot fill hole.

In order to alleviate the drawbacks mentioned above, some manufacturers use flexible material for base of light-emitting element. Reference is made to FIG. 1B, which is sectional view of a conventional flexible light-emitting element.

The light-emitting element includes a flexible base 80, an electrically conductive layer 82, an adhesive layer 84, and a plurality of light-emitting chips 86. The electrically conductive layer 82 is combined with the flexible base 80 via the adhesive layer 84. The light-emitting chips 86 are electrically connected to the electrically conductive layer 82. Therefore, the light-emitting element has a characteristic of flexibility, and can be applied to an irregular surface. However, the flexible base 80 is made of resin with pool thermal conduction, such that the heat generated from the light-emitting chips 86 cannot be effectively conducted, which causes the illuminant efficient of the light-emitting chip 84 decreases. Moreover, the adhesive layer 84 is also with pool thermal conduction, which also causes poor heat dissipation of the light-emitting chips 86 and lower illuminant efficient of the light-emitting chips 86.

### SUMMARY OF THE INVENTION

It is an object to provide a light emitting element with characteristic of flexible and good thermal conductive effect to improve the loss cost of cutting tool and the problem of fragile base. Accordingly, the light-emitting element according to one aspect of the present invention comprises two electrically conductive layers, a flexible insulating layer, a light-emitting chip, and an encapsulating body. A groove is formed between the electrically conductive layers. The flexible insulating layer is disposed within the groove and links the electrically conductive layers. The light-emitting chip is placed on one of the electrically conductive layers or crossing over the flexible insulating layer. The light-emitting chip is electrically connected to the electrically conductive layers and covered by the encapsulating body.

In an embodiment of the present invention, an upper surface of the flexible insulating layer and an upper surface of each electrically conductive layer are at the same level.

According to a preferred embodiment of the invention, wherein a thickness of the flexible insulating layer is smaller than 200 micrometers.

According to a preferred embodiment of the invention, wherein a thickness of each electrically conductive layer is larger than 10 micrometers.

Accordingly, the light-emitting element according to another aspect of the present invention comprises at least two first electrically conductive layers, a flexible insulating layer, at least two second electrically conductive layer, at least one light-emitting chip, and an encapsulating body. A groove is formed between the first electrically conductive layers. The flexible insulating layer is disposed under the groove and links the first electrically conductive layers. The second electrically conductive layers is correspondingly disposed under the first electrically conductive layer, and a lower surface of each second electrically conductive layer and a lower surface of the flexible insulating layer are at the same level. The light-emitting chip is electrically connected to the first electrically conductive layers and covered by the encapsulating body.

According to a preferred embodiment of the invention, wherein the light-emitting chip crosses over the flexible insulating layer, an electrode of the light-emitting chip is electrically connected to one of the first electrically conductive layer, and the other electrode of the light-emitting chip is electrically connected to the other first electrically conductive layer.

According to a preferred embodiment of the invention, wherein the encapsulating body at least partially disposed within the groove to tightly cover the light-emitting chip.

According to a preferred embodiment of the invention, the light-emitting element further comprises at least one conductive wire crossing over the groove, the light-emitting chip is disposed on one of the first electrically conductive layers, one end of the conductive wire is connected to an electrode of the light-emitting chip, and the other end of the conductive wire is connected to the other electrode of the light-emitting chip.

According to a preferred embodiment of the invention, wherein a thickness of the flexible insulating layer is smaller than 200 micrometer.

According to a preferred embodiment of the invention, wherein a thickness of the first electrically conductive layers is larger than 10 micrometers.

According to a preferred embodiment of the invention, wherein a width of the flexible insulating layer is equal to a width of the groove.

According to a preferred embodiment of the invention, wherein a width of the flexible insulating layer is larger than a width of the groove.

According to a preferred embodiment of the invention, wherein the width of the flexible insulating layer is uniform.

According to a preferred embodiment of the invention, wherein the width of the flexible insulating layer is progressively increased along a direction away from the first electrically conductive layers.

According to a preferred embodiment of the invention, wherein the width of the flexible insulating layer is progressively decreased along a direction away from the first electrically conductive layers.

According to a preferred embodiment of the invention, the light-emitting element further comprises at least two third electrically conductive layers correspondingly disposed under the second electrically conductive layers.

According to a preferred embodiment of the invention, the light-emitting element further comprises an intermediary layer disposed under the second electrically conductive layer.

According to a preferred embodiment of the invention, wherein the light-emitting element further comprises at least two third electrically conductive layers disposed under the intermediary layer.

According to a preferred embodiment of the invention, wherein the light-emitting element comprises a plurality of first electrically conductive layers and a plurality of light-emitting chips, a groove is formed between each two first electrically conductive layers, the flexible insulating layer is disposed under each groove and links each two electrically conductive layers, each light-emitting chip is placed on one of the first electrically conductive layers or crossing over the flexible insulating layer, the light-emitting chips are electrically connected in series and parallel via the first electrically conductive layers.

Accordingly, a manufacturing method for light-emitting element according to still another aspect of the present invention comprises: a) providing a first electrically conductive layer and a flexible insulating layer disposed under the first electrically conductive layer; b) forming at least one groove on the first electrically conductive layer; c) removing partially flexible insulating layer so that the first electrically conductive layer is at least partially exposed out of the flexible insulating layer; d) forming a second electrically conductive layer on the first electrically conductive layer exposed from the flexible insulating layer, and a lower surface of the second electrically conductive layer and a lower surface of the flexible insulating layer being at the same layer; e) disposing at least one light-emitting chip on the electrically conductive layer or crossing over the flexible insulating layer; and f) forming an encapsulating body covering the light-emitting chip.

According to a preferred embodiment of the invention, the manufacturing method of the present invention further comprises: forming an intermediary layer under the second electrically conductive layer.

According to a preferred embodiment of the invention, the manufacturing method of the present invention further comprises: forming a third electrically conductive layer under the second electrically conductive layer or the intermediary layer.

Accordingly, a manufacturing method for light-emitting element according to still another aspect of the present invention comprises: a) providing an electrically conductive layer; b) forming at least one groove on the electrically conductive layer; c) disposing a flexible insulating layer within the groove; d) disposing at least one light-emitting chip on the electrically conductive layer or crossing over the flexible insulating layer, and e) forming an encapsulating body covering the light-emitting chip.

### BRIEF DESCRIPTION OF DRAWING

The features of the invention believed to be novel are set forth with particularity in the appended claims. The invention itself, however, may be best understood by reference to the following detailed description of the invention, which describes an exemplary embodiment of the invention, taken in conjunction with the accompanying drawings, in which:

FIG. 1A is a sectional view of conventional light-emitting element;

FIG. 1B is a sectional view of conventional flexible light-emitting element;

FIG. 2 to FIG. 26 are diagrams showing manufacturing methods for light-emitting element according to the present invention;

FIG. 27 is a schematic view of a lighting module according to a first embodiment of the present invention; and

FIG. 28 is a schematic view of a lighting module according to a second embodiment of the present invention.

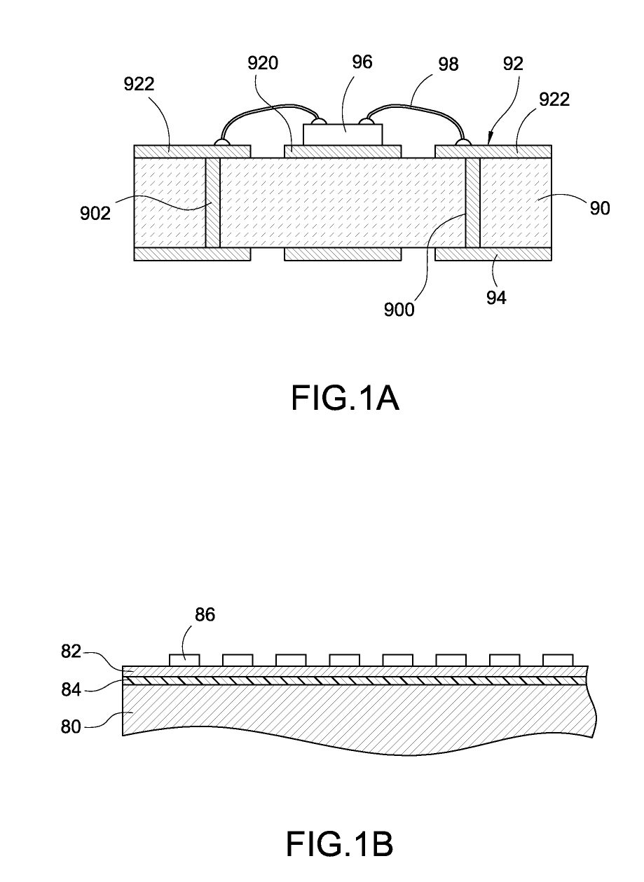

### DETAILED DESCRIPTION OF THE INVENTION

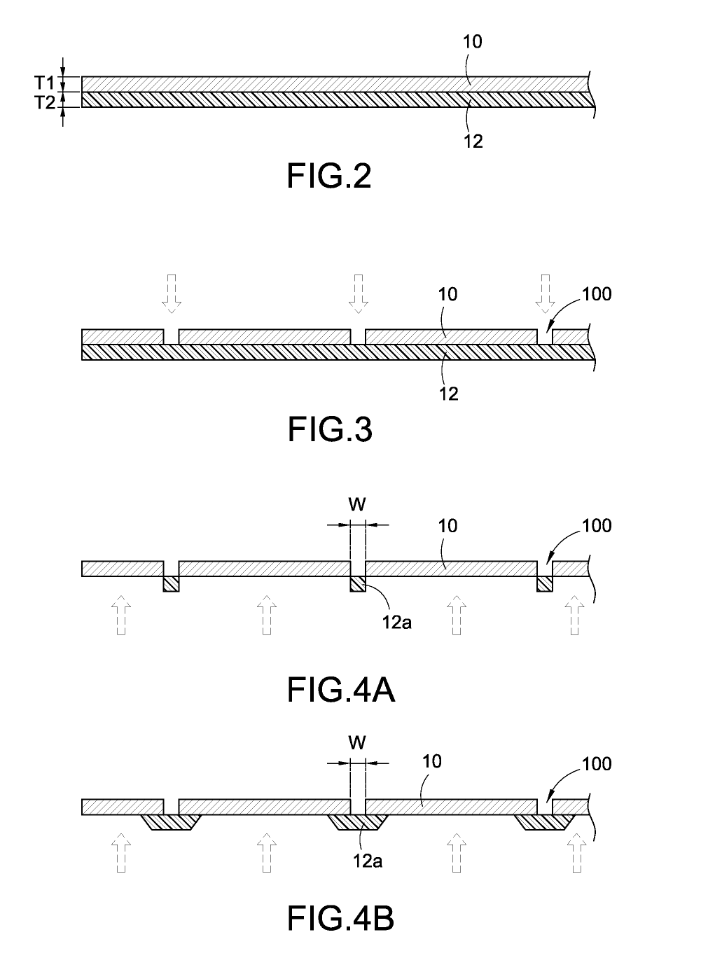

Reference will now be made in detail to the present embodiments of the invention, examples of which are illustrated in the accompanying drawings. Reference is made to FIG. 2 to FIG. 11, which are diagrams showing a manufacturing method for light-emitting element according to a first embodiment of the present invention. The light-emitting element is for example, but not limited to, light emitting diode (LED).

Reference is made to FIG. 2, a first electrically conductive layer 10 with plate form and a flexible insulating layer 12 with plate form are provided. The flexible insulating layer 12 is disposed under the first electrically conductive layer 10. The first electrically conductive layer 10 is preferably combined with the flexible insulating layer 12 by calendaring.

The first conductive layer 10 is made of material with good electrically conductive characteristic for providing good electrically conductive effect. The first electrically conductive layer 10 is preferably metal. Moreover, the first electrically conductive layer 10 also has good thermal conductive characteristic for providing good thermal conductive effect. A thickness T1 of the first electrically conductive layer 10 is larger than 10 micrometers. The thickness T1 of the first electrically conductive layer 10 is preferably 175 micrometers.

The flexible insulating layer 12 is made of flexible material, such as photo resistance, polymide (PI), polythylene terphthalate (PET), polyolefins (PO), plastic or macromolecular polymer. A thickness T2 of the flexible insulating layer 12 is smaller than 200 micrometers. The thickness T2 of the flexible insulating layer 12 is preferably 125 micrometers.

Reference is made to FIG. 3, at least one groove 100 is formed on the first electrically conductive layer 10. The groove 100 can be formed by wet etching, dry etching, laser cutting or grinding. The amount of the groove 100 may be one or more, and in this embodiment, the first electrically conductive layer 12 includes, for example, three grooves 100.

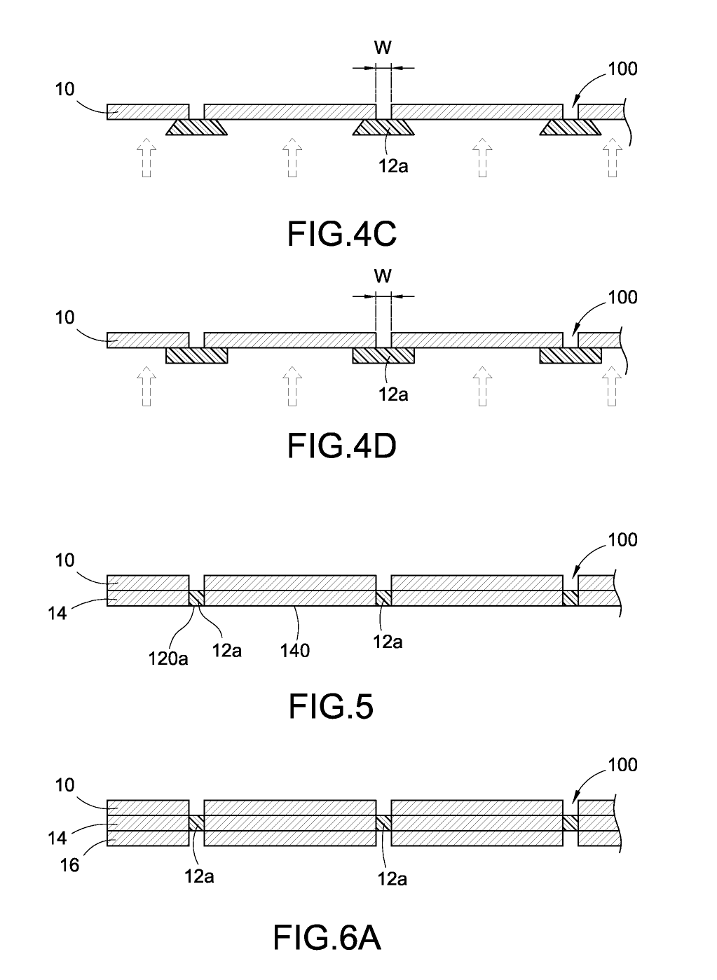

After that, partial flexible insulating layer 12 is removed to expose the first electrically conductive layer 10 to the flexible insulating layer 12. A flexible insulating layer 12a, which is not removed, links the first electrically conductive layers 10 at two sides of each groove 100, as shown in FIG. 4A to FIG. 4D. The method for removing the flexible insulating layer 12 is, for example, wet etching, dry etching or laser cutting.

In FIG. 4A, a profile of the flexible insulating layer 12a is substantially square, and a width of the flexible insulating layer 12a is substantially equal to a width W of each groove 100. In FIG. 4B to FIG. 4D, a width of the flexible insulating layer 12a is larger than the width W of each groove 100, such that the bond strength of the flexible insulating layer 12a and the first electrically conductive layers 10 is improved. In FIG. 4B, the width of the flexible insulating layer 12a is progressively decreased along a direction away from the first electrically conductive layers 12, such that the flexible insulating layer 12a has profile of inverted trapezium. In FIG. 4C, the width of the flexible insulating layer 12a is progressively increased along a direction away from the first electrically conductive layers 10, such that the flexible insulating layer 12a in FIG. 4C has profile of regular trapezoid. In FIG. 4D, the flexible insulating layer 12a is rectangular.

After removing partial flexible insulating layer 12, a second electrically conductive layer 14 is disposed under the first electrically conductive layer 10, and a lower surface 140 of the second electrically conductive layer 14 and a lower surface 120a of the flexible insulating layer 12a are at the same level, as shown in FIG. 5. The flexible insulating layer 12a shown in FIG. 5 has the same profile as shown in FIG. 4A. However, in the practical application, the flexible insulating layer 12a shown in FIG. 5 has the same profile as shown in FIG. 4B, FIG. 4C or FIG. 4D. The second electrically conductive layer 14 is disposed under the first electrically conductive layer 10 by electroplating, chemical deposition, deposition, sticking or sputtering deposition for increasing electrically conduction and thermal conduction. The second electrically conductive layer 14 is made of material with good electrically conductive characteristic. The manufacturing material of the second electrically conductive layer 14 is preferably the same as the manufacturing material of the first electrically conductive layer 10.

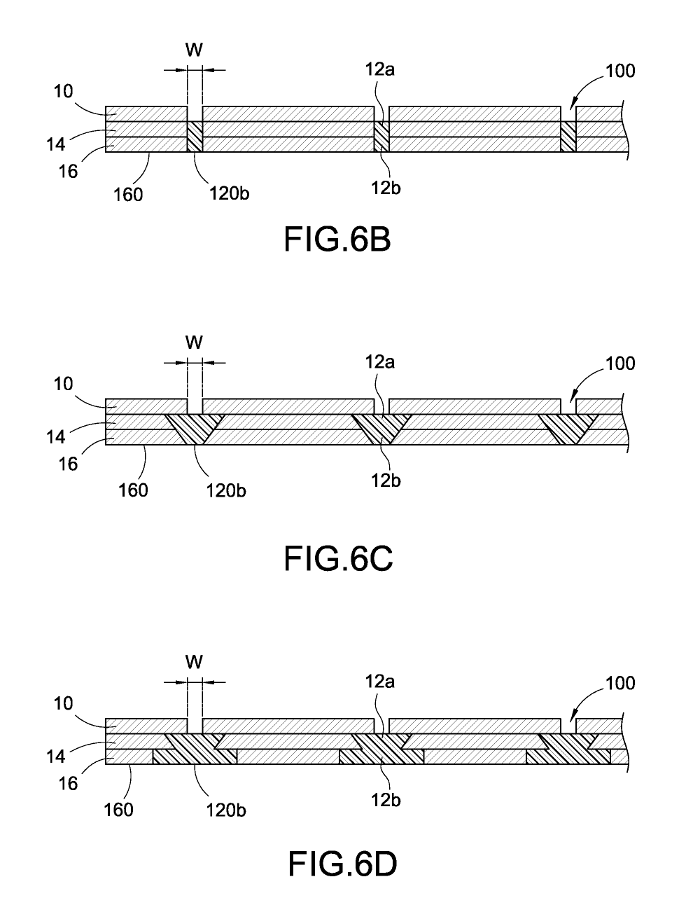

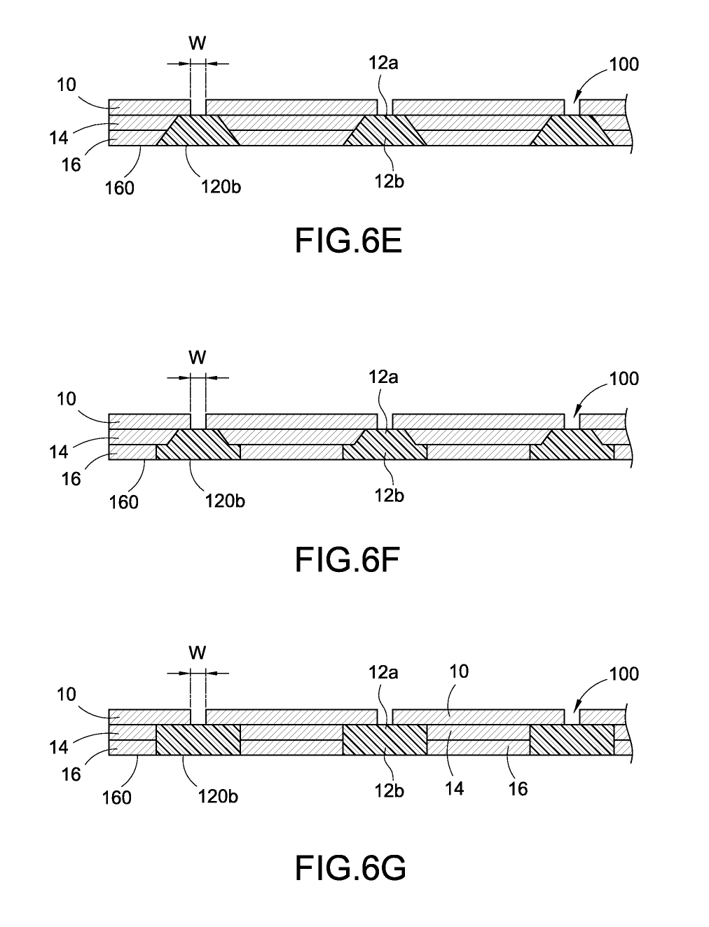

The light-emitting element may selectively include a third electrically conductive layer 16. The third electrically conductive layer 16 is disposed under the second electrically conductive layer 14, as shown in FIG. 6A to 6G. The third electrically conductive layer 16 further increases the electrically conductivity and thermal conductivity of the light-emitting element. The third electrically conductive layer 16 is disposed under the second electrically conductive layer 14 by electroplating, chemical deposition, deposition, sticking or sputtering deposition for increasing electrically conduction and thermal conduction. The third electrically conductive layer 16 is made of material with good electrically conductive characteristic. The manufacturing material of the third electrically conductive layer 16 is preferably the same as the manufacturing material of the first electrically conductive layer 10.

As shown in FIG. 6A, a recess is formed between two adjacent third electrically conductive layers 16. As shown in FIG. 6B to FIG. 6G, a flexible insulating layer 12b is disposed between two adjacent third electrically conductive layers 16, and a lower surface 120b of the flexible insulating layer 12b and a lower surface 160 of each third electrically conductive layer 16 are at the same level. The flexible insulating layer 12a and the flexible insulating layer 12b may be made at the same process. However, the flexible insulating layer 12b may be filled in the recess formed between adjacent third electrically conductive layers 16 after disposing the third electrically conductive layer 16 under the second electrically conductive layer 14.

In FIG. 6B, the flexible insulating layers 12a and 12b are respectively square, and the widths of the flexible insulating layers 12a and 12b are substantially equal to the width W of each groove 100. In FIG. 6C, the width of the flexible insulating layer 12a is larger than the width W of each groove 100, and is progressively decreased along a direction away from the first electrically conductive layer 12. The width of the flexible insulating layer 12b is smaller than that of the flexible insulating layer 12a, and is progressively decreased along a direction away from the second electrically conductive layer 14. In FIG. 6D, the width of the flexible insulating layer 12a is larger than the width W of each groove 100, and is progressively decreased along a direction away from the first electrically conductive layer 10. The flexible insulating layer 12b is substantially square, and the width of the flexible insulating layer 12b is larger than that of the flexible insulating layer 12a. In FIG. 6E, the width of the flexible insulating layer 12a is larger than the width W of each groove 100, and is progressively increased along a direction away from the first electrically conductive layer 10. The width of the flexible insulating layer 12b is larger than that of the flexible insulating layer 12a, and is progressively increased along a direction away from the second electrically conductive layer 14. In FIG. 6F, the width of the flexible insulating layer 12a is larger than the width W of each groove 100, and is progressively increased along a direction away from the first electrically conductive layer 10. The width of the flexible insulating layer 12b is larger than that of the flexible insulating layer 12b, and is substantially rectangular. In FIG. 6G, the flexible insulating layers 12a and 12b are substantially rectangular, and the widths of the flexible insulating layers 12a and 12b are larger than the width W of each groove 100.

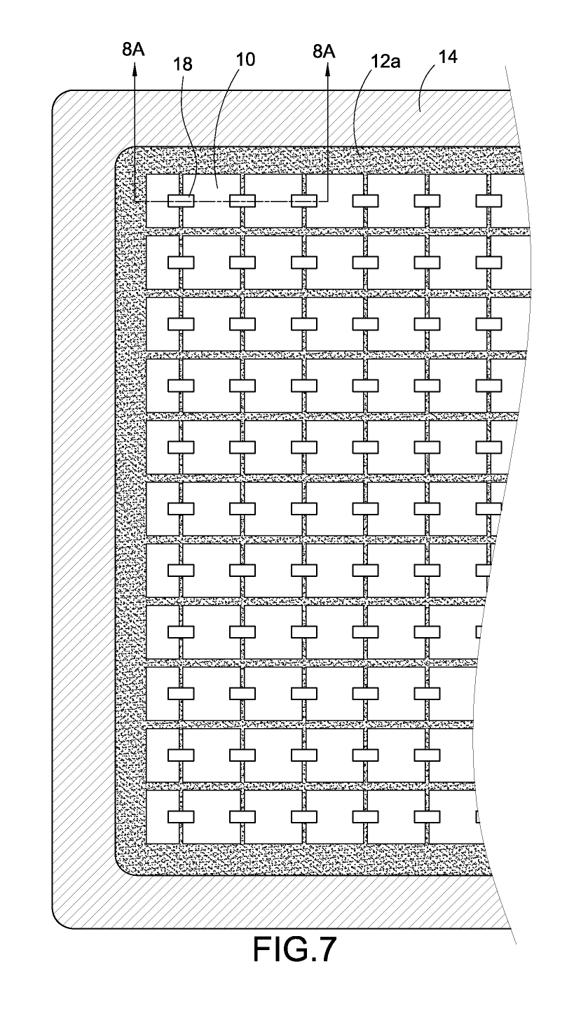

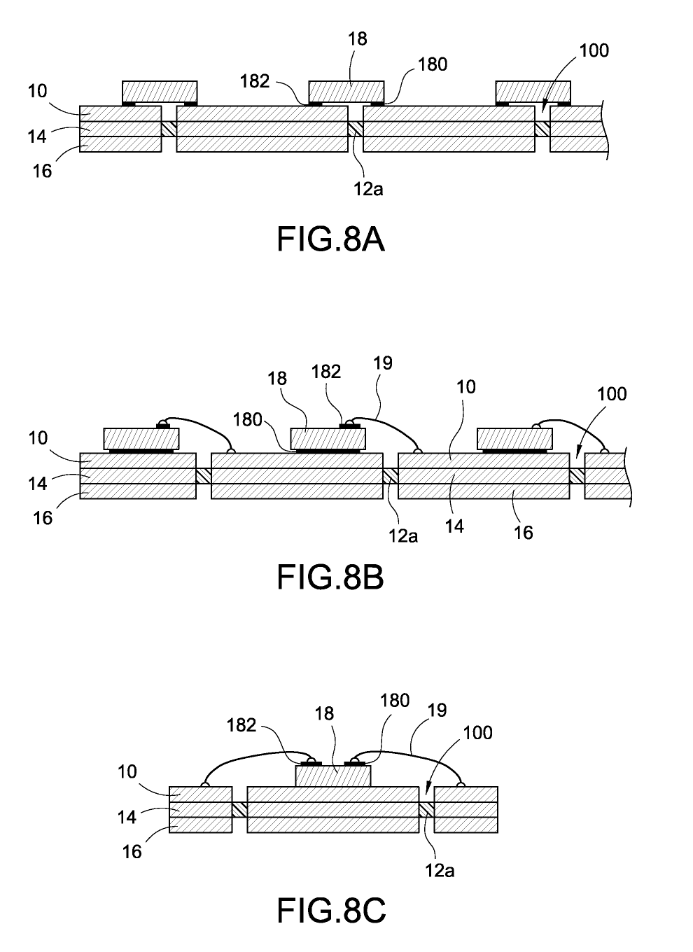

After that, at least one light-emitting chip 18 is placed on the first electrically conductive layer 10, as shown in FIG. 7 to FIG. 8C. The amount of the light-emitting chip 18 may be one or more, and the light-emitting chip 18 is light-emitting diode (LED). Each light-emitting chip 18 is placed on one of the electrically conductive layers 10 or crossing over the flexible insulating layer 12a. Each light-emitting chip 18 is electrically connected to the first electrically conductive layer 10.

Reference is made to FIGS. 7 and 8A, FIG. 8A is a sectional view of line 8A-8A shown in FIG. 7. The light-emitting chip 18 is a flip-chip LED chip and crossing over the groove 100 (namely, the light-emitting chips 18 cross over the flexible insulating layer 12a). Two electrodes 180 and 182 of each light-emitting chip 18 are respectively contacted with the first electrically conductive layer 10 located at two sides of each groove 100 and electrically connected thereto.

Reference is made to FIG. 8B, the light-emitting chips 18 are vertical structure LED chips. Each light-emitting chip 18 is placed on one of the first electrically conductive layers 10, one electrode 180 of each light-emitting chip 18 is directly contacted with the first electrically conductive layer 10 and electrically connected thereto. The other electrode 182 of each light-emitting chip 180 is electrically connected to the other first electrically conductive layer 10 located at the other side of each groove 100 via a soldering wire 19 crossing over the groove 100.

Reference is made to FIG. 8C, the light-emitting chips 18 are horizontal structure LED chips. Each light-emitting chip 18 is placed on one of the first electrically conductive layers 10, and electrically connected to other electrically conductive layers 10 located at the other sides of each groove 100 via two soldering wires 19. In this embodiment, the soldering wires 19 are connected to the first electrically connected layer 10 not carrying the light-emitting chip 18. However, in the practical application, one of the soldering wires 19 may electrically connect to the first electrically conductive layer 10 carrying the light-emitting chip 18.

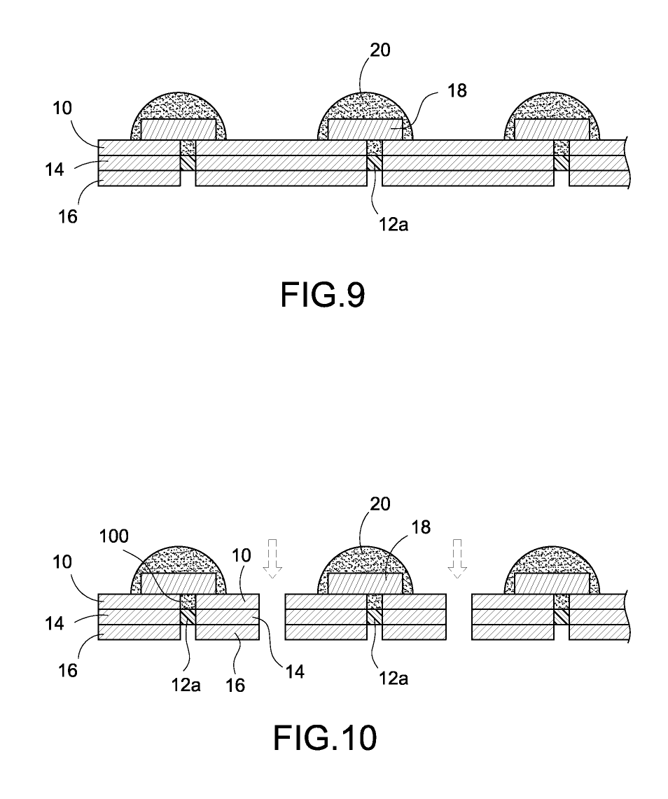

Reference is made to FIG. 9, an encapsulating body 20 is formed for covering the light-emitting chips 18. The encapsulating body 20 is simultaneously and partially filled within the groove 100 for tightly covering the light-emitting chips 18. In particularly, the placing manner of the light-emitting chips 18 shown in FIG. 9 is the same as shown in FIG. 8A. However, in the practical application, the placing manner of the light-emitting chips 18 shown in FIG. 9 may be the same as FIG. 8B or FIG. 8C. The encapsulating body 20 is a transparent resin, and preferably made of silicone. In this embodiment, the encapsulating body 20 covers only one light-emitting chip 18, and a profile of the encapsulating body 20 is hemisphere for increasing light extraction. However, in the practical application, the profile of the encapsulating body 20 may be adjusted according to demanded light intensity distribution. A wavelength converting matter, such as phosphor, may be disposed within the encapsulating body 20 for converting a part of light emitted from the light-emitting chip 18 into wavelength-converted light.

Reference is made to FIG. 10, a plurality of light-emitting elements are formed by cutting along the outside of each encapsulating body 20.

Therefore, the light-emitting element according to one aspect of the present invention is shown in FIG. 10. The light-emitting element includes at least two first electrically conductive layers 10, a flexible insulating layer 12, at least two second electrically conductive layers 14, at least one light-emitting chip 18, and encapsulating body 20. A groove 100 is formed between the first electrically conductive layers 10. The flexible insulating layer 12 is disposed under the groove 100 and links the first electrically conductive layers 10. The second electrically conductive layers 14 are correspondingly disposed under the first electrically conductive layers 10, and a lower surface 140 of each second electrically conductive layer 14 and a lower surface of the flexible insulating layer 12 are at the same level. The light-emitting chip 18 is placed on one of the first electrically conductive layers 10 or crossing over the flexible insulating layer 12. The light-emitting chip 18 is electrically connected to the electrically conductive layers 10. The encapsulating body 20 covers the light-emitting chip 18 and is partially filled within the groove 100 for tightly covering the light-emitting chip 18.

The light-emitting element may selectively include at least two third electrically conductive layers 16. The third electrically conductive layers 16 are correspondingly disposed under the second electrically conductive layers 14 for increasing the electrically conductivity and thermal conductivity.

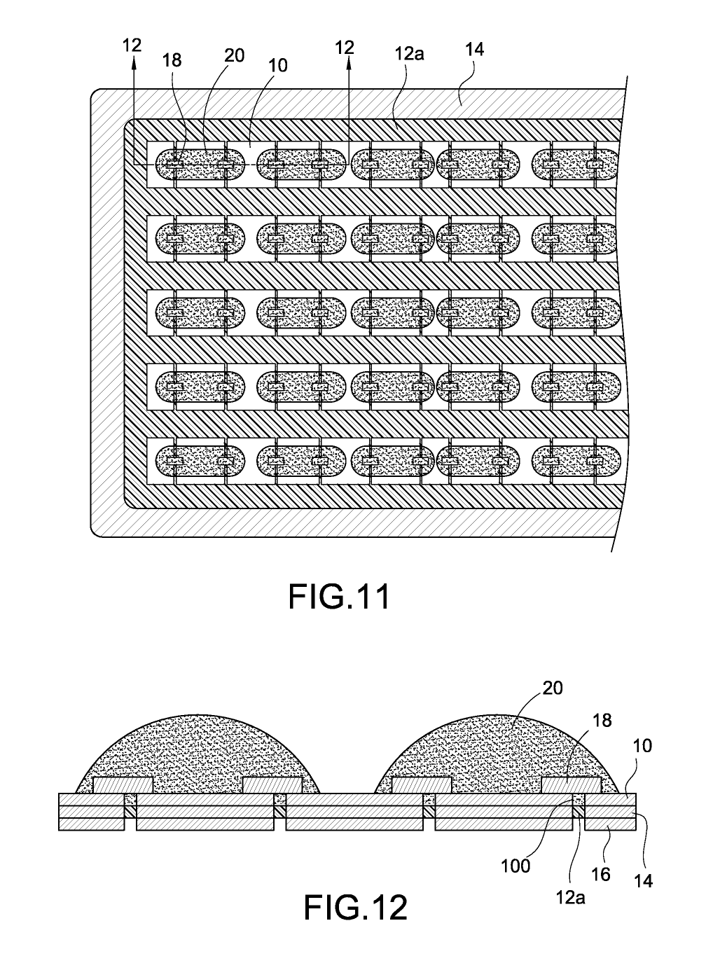

Besides, the encapsulating body 20 may also cover multiple light-emitting chips 18, as shown in FIG. 11 to FIG. 14. Reference is made to FIG. 11 and FIG. 12, wherein FIG. 12 is a sectional view along line 12-12 shown in FIG. 11. The encapsulating body 20 covers two light-emitting chips 18, and the light-emitting chips 18 are electrically connected in series. However, in the practical application, the light-emitting element may include two light-emitting chips 18 covered by the encapsulating body 20, or the light-emitting element may also include multiple light-emitting chips 18, wherein each two light-emitting chips 18 is covered by the encapsulating body 20, and each of two adjacent light-emitting chips 18 is electrically connected in series via the first electrically conductive layer 10 for providing strip lighting source.

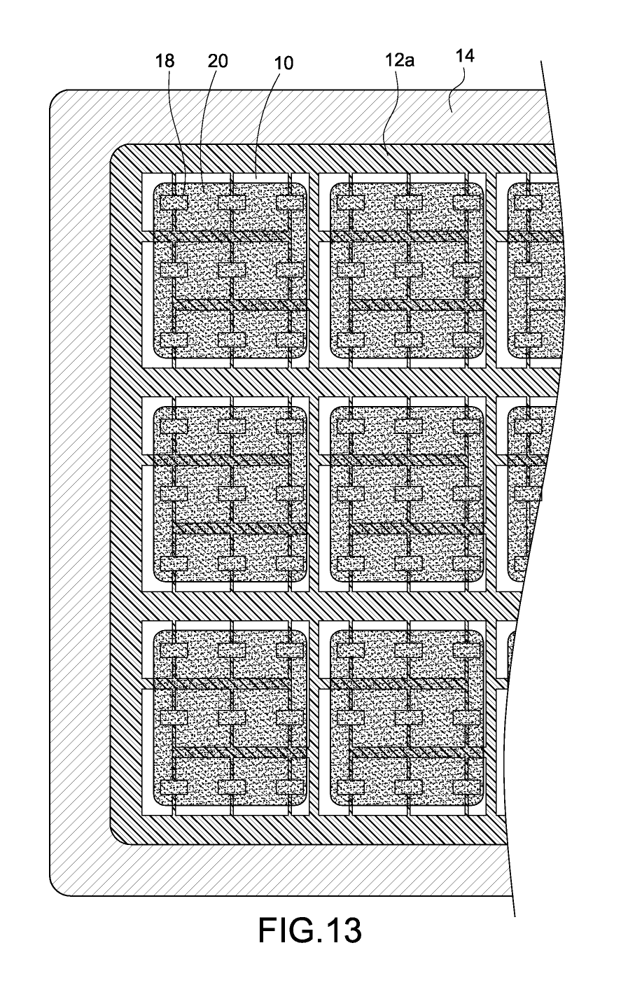

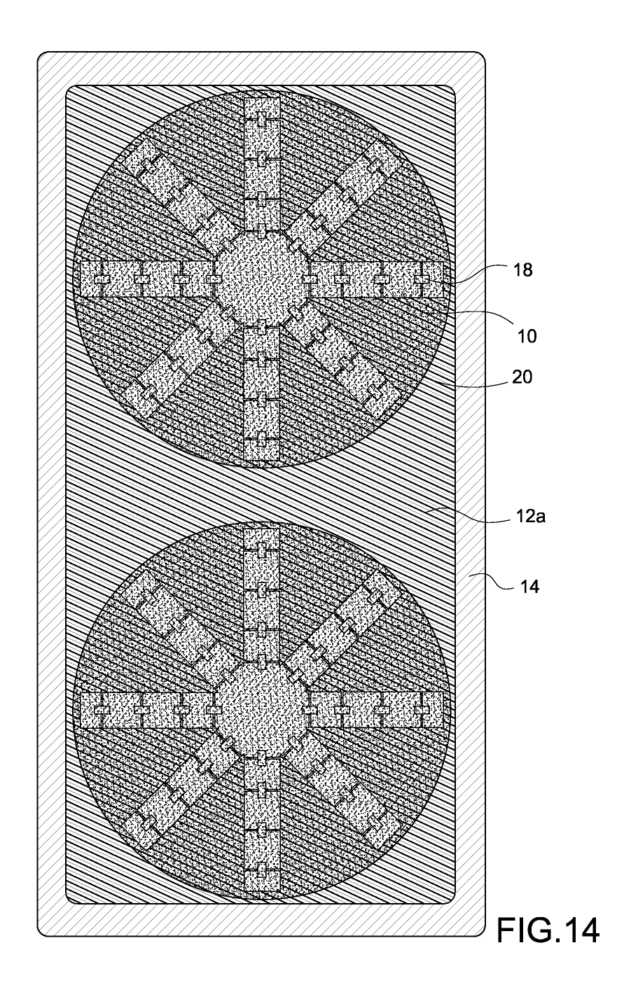

Reference is made to FIG. 13, the encapsulating body 20 covers nine light-emitting chips 18, and the light-emitting chips 18 are in series and parallel connection. Reference is made to FIG. 14, the first electrically conductive layers 10 are arranged with a particular pattern (such as circle). A plurality of light-emitting chips 18 cross over the grooves 100 (namely, the light-emitting chips 18 cross over the flexible insulating layer 12a). The light-emitting chips 18 are electrically connected to the first electrically conductive layer 10 for providing a lighting source with particular light intensity distribution. In FIG. 11 to FIG. 14, each light-emitting chip 18 is, for example, crossing over flexible insulating layer 12. However, in the practical application, each light-emitting chip 18 may be placed on one of the first electrically conductive layers 10, and electrically to the other first electrically conductive layer 10 located at the other side of each groove 100 via at least one soldering wire.

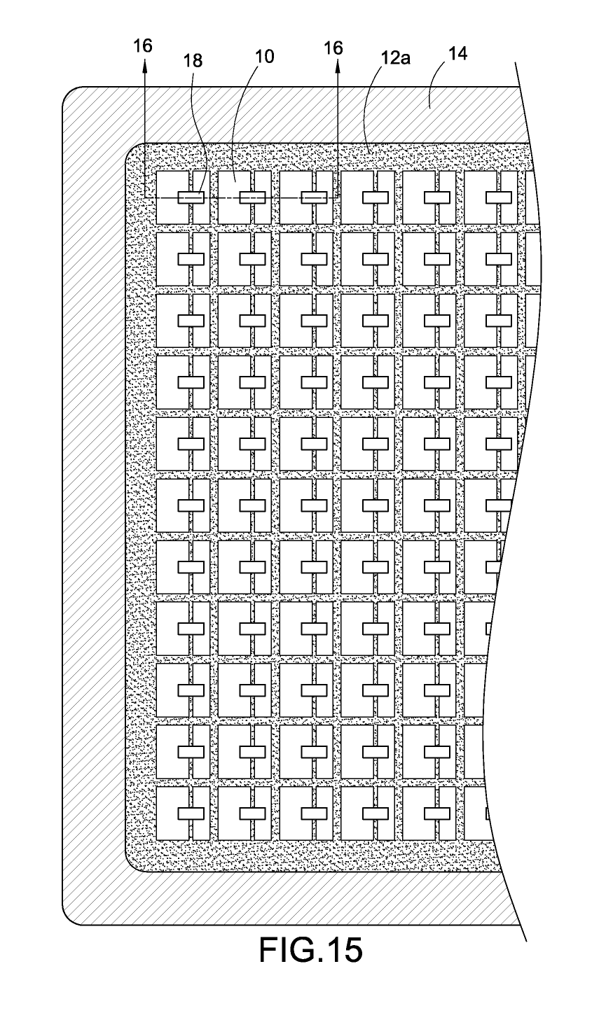

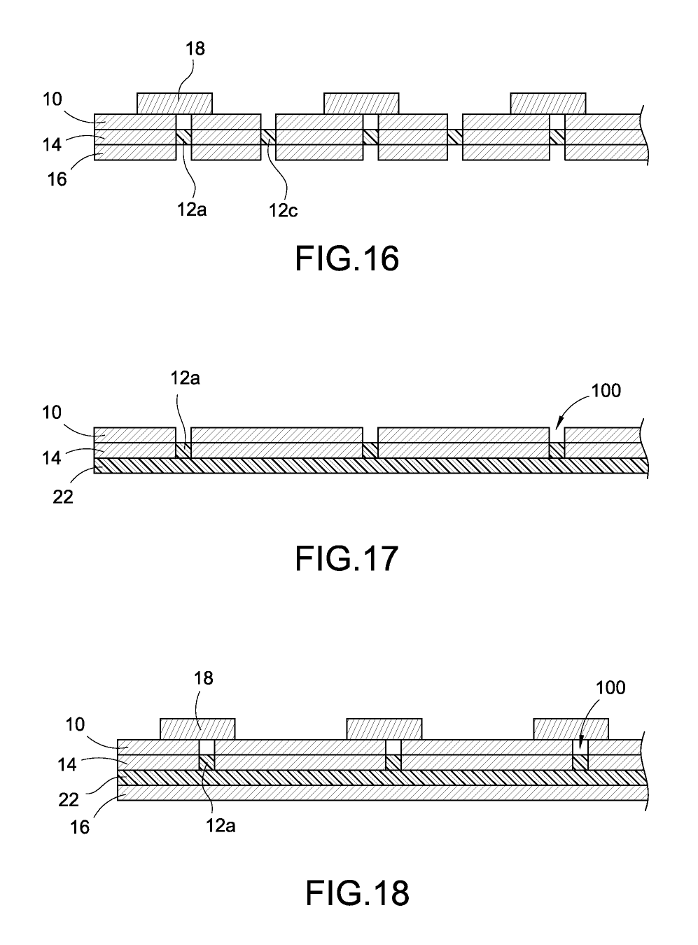

In order to prevent the first electrically conductive layers 10, the second electrically conductive layers 14, and the third electrically conductive layers 16 from damaging and the risk of failing to provide electrically conductive property when the light-emitting element is cut, the light-emitting element may selectively dispose a flexible insulating layer 12c between the first electrically conductive layers 10 of two adjacent light-emitting elements, as shown in FIG. 15 and FIG. 16. In particularly, FIG. 16 is a sectional view of 16-16 line shown in FIG. 15. The manufacturing material of the flexible insulating layer 12c is the same as that of the flexible insulating layer 12a. The flexible insulating layer 12c is disposed within partial grooves 100 formed on the first electrically conductive layer 10. A profile of the flexible insulating layer 12c is substantially square, and a width of the flexible insulating layer 12c is changed by cutting tool. Therefore, multiple light-emitting elements are formed while the cutting tool cuts the light-emitting elements along the flexible insulating layer 12c, and the damage probability is also reduced.

To sum up, the light-emitting element of this embodiment uses the flexible insulating layer 12a disposed under the groove 100 to link adjacent first electrically conductive layers 10 so that the light-emitting element is flexible and can be applied on irregular surfaces.

Reference is made to FIG. 2 to FIG. 5 and FIG. 17 to FIG. 20, which are diagrams showing a manufacturing method for light-emitting element according to a second embodiment of the present invention. FIG. 17 is a diagram follows FIG. 5, and FIG. 2 to FIG. 5 are the same as mentioned in the first embodiment, and the detail thereof is not described here for brevity

After disposing the second electrically conductive layers 14 under the first electrically conductive layers 10, an intermediary layer 22 is formed under the second electrically conductive layer 14. The intermediary layer 22 formed under the second electrically conductive layer 14 is made of insulating material, such as photo resistance, PI, PET, PO, plastic or macromolecular polymer, by coating, deposition, sputtering deposition or chemical vapor deposition.

After that, a third electrically conductive layer 16 is disposed under the intermediary layer 22, as shown in FIG. 18, and then at least one light-emitting chip 18 crosses over the groove 100 (namely, the light-emitting chip 18 crosses over the flexible insulating layer 12a) and electrically connected to the first electrically conductive layers 10. The amount of the light-emitting chip 18 may be one or more. In this embodiment, the amount of the light-emitting chips 19 is three, and the light-emitting chips are LEDs. Each of the light-emitting chip 18 crosses over the flexible insulating layer 18 and is electrically connected to first electrically conductive layers 10. However, in the practical application, each light-emitting chip 18 may be disposed on one of the first electrically conductive layers 10 and is electrically connected to first electrically conductive layers 10.

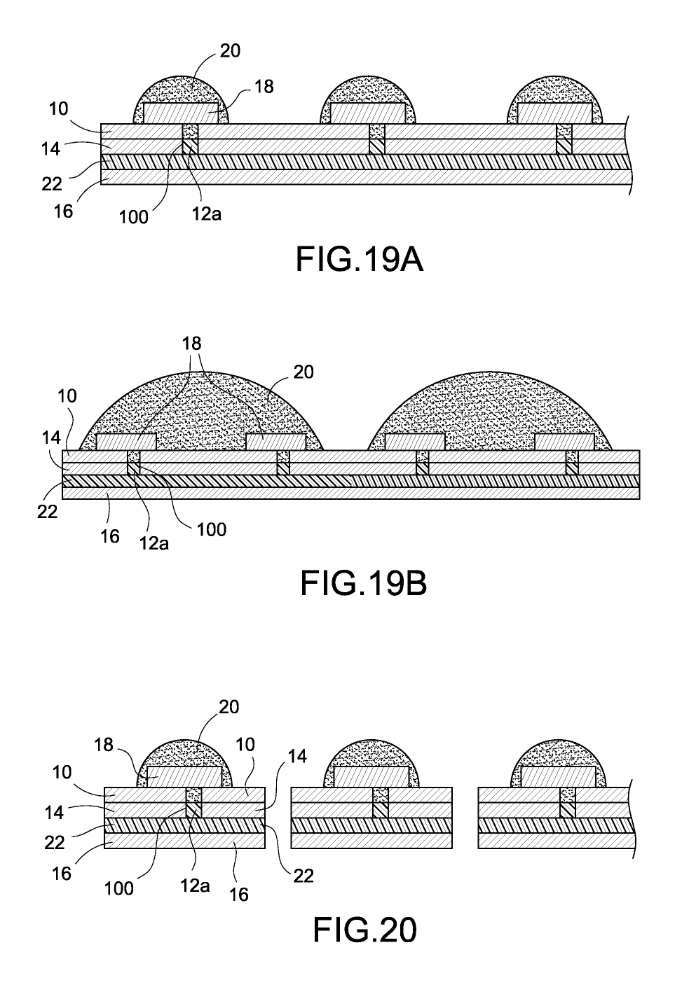

Reference is made to FIG. 19A to FIG. 19B, an encapsulating body 20 is formed for covering the light-emitting chips 18 and partially filled within the grooves 100 so that the light-emitting chips 18 are tightly covered by the encapsulating body 20. The encapsulating body 20 is transparent resin, and preferably the encapsulating body 20 is silicone resin. A profile of the encapsulating body 20 is hemisphere for increasing light extraction. However, in the practical application, the profile of the encapsulating body 20 may be changed according to demanded light intensity distribution. The encapsulating body 20 may covers only one light-emitting chip 18, as shown in FIG. 19A. However, the encapsulating body 20 may also covers multiple light-emitting chips 18, as shown in FIG. 19B, and the light-emitting chips 18 are electrically connected in series and parallel.

Reference is made to FIG. 20, a plurality of light-emitting elements are formed by cutting along the outside of each encapsulating body 20. In FIG. 20, the encapsulating body 20 covers only one light-emitting chip 18 (the same as shown in FIG. 19A) as an example, however, in the practical application, the encapsulating body 20 may cover multiple light-emitting chips 18.

Therefore, the light-emitting element according to another aspect of the present invention is shown in FIG. 20. The light-emitting element includes two first electrically conductive layers 10, a flexible insulating layer 12a, two electrically conductive layers 14, a light-emitting chip 18, an encapsulating body 22, and an intermediary layer 22. A groove 100 is formed between the electrically conductive layers 10. The flexible insulating layer 12a is disposed under the groove 10 and links the electrically conductive layers 10. The second electrically conductive layers 14 are correspondingly disposed under the first electrically conductive layers 10, and a lower surface of each second electrically conductive layer 14 and a lower surface of the flexible insulating layer 12a are at the same level. The light-emitting chip 18 is placed on one of the first electrically conductive layers 10 or crosses over the flexible insulating layer 12a. The light-emitting chip 18 is electrically connected to the first electrically conductive layers 10. The encapsulating body 20 covers the light-emitting chip 18 and partially filled within the groove 100 for tightly covering the light-emitting chip 18. The intermediary layer 22 is disposed under the second electrically conductive layers 12. The light-emitting element may selectively include two third electrically conductive layers 16 correspondingly disposed under the intermediary layer 22.

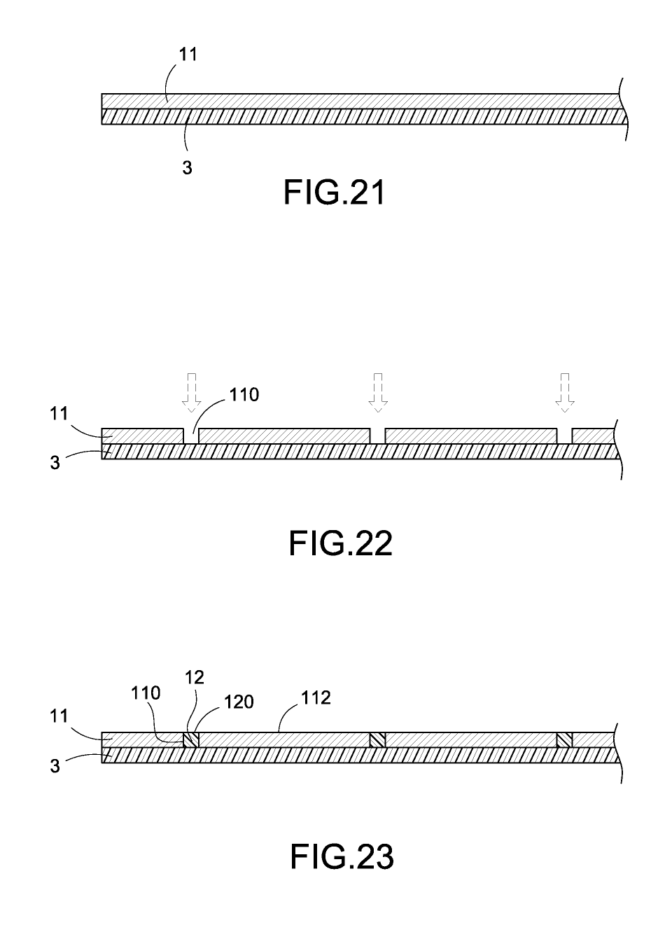

Reference is made to FIG. 21 to FIG. 26, which are diagrams showing a manufacturing method for light-emitting element according to a third embodiment of the present invention.

Reference is made to FIG. 21, an electrically conductive layer 11 is provided. The electrically conductive layer 11 is disposed on a temporary base 3. The electrically conductive layer 11 is made of material with good electrically conductive property for providing good electrically conductive effect. The electrically conductive layer 11 is preferably metal. The electrically conductive layer 11 also has good thermal conductive coefficient for providing good thermal conductive effect. The electrically conductive layer 11 may combine with the temporary base 3 via a thermal release tape (not shown).

Reference is made to FIG. 22, a plurality of grooves 110 are formed on the electrically conductive layer 11. The groove 110 can be formed by wet etching, dry etching, laser cutting or grinding.

Reference is made to FIG. 23, a flexible insulating layer 12 is disposed within the grooves 110. The flexible insulating layer 12 links the electrically conductive layers 11 located at two sides of each groove 100, and an upper surface 120 of the flexible insulating layer 12 and an upper surface 112 of each electrically conductive layer 11 are at the same level. The flexible insulating layer 12 is made of flexible material, such as photo resistance, PI, PET, PO, plastic or macromolecular polymer.

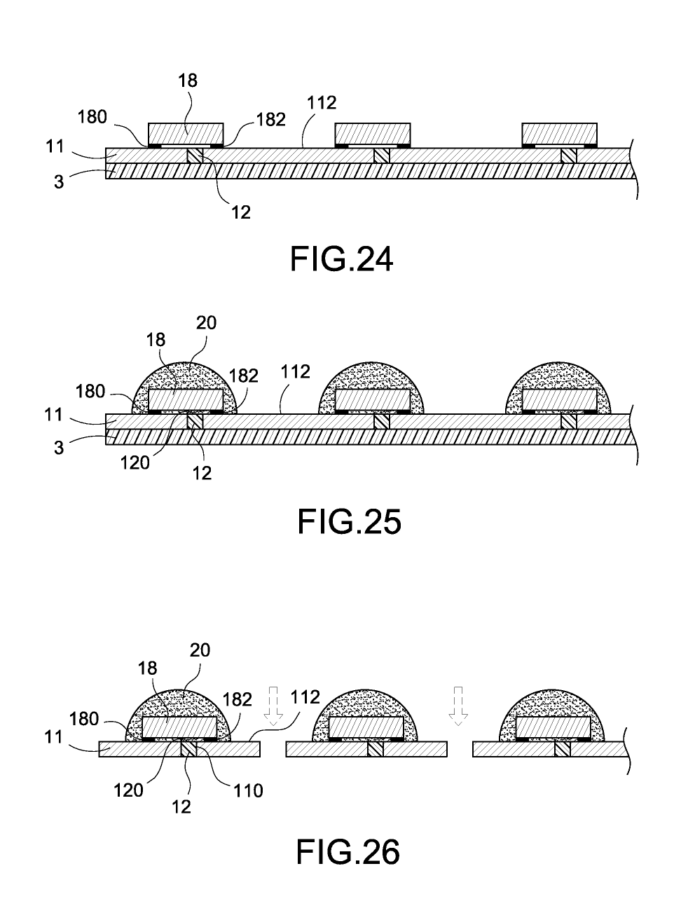

Reference is made to FIG. 24, a plurality of light-emitting chips 18 cross over the flexible insulating layer 12 and electrically connected to the electrically conductive layer 11. In this embodiment, the light-emitting chips 18 are flip-chip LEDs. Two electrodes 180 and 182 are respectively contacted with the electrically conductive layer 11 located at both sides of the flexible insulating layer 12 and electrically connected thereto. However, in the practical application, each light-emitting chip may be vertical structure LED or horizontal structure LED. Each light-emitting chip 18 may be placed on one of the electrically conductive layers 11, and electrically to the other electrically conductive layer 11 via at least one soldering wire crossing over the flexible insulating layer 12.

Reference is made to FIG. 25, an encapsulating body 20 is formed for covering the light-emitting chips 18. The encapsulating body 20 is transparent resin, and in preferably, the encapsulating body 20 is silicone resin. A profile of the encapsulating body 20 is hemisphere for increasing light extraction. However, in the practical application, the profile of the encapsulating body 20 may be changed according to demanded light intensity distribution. In this embodiment, the encapsulating body 20 covers only one light-emitting chip 18. However, in the practical application, the encapsulating body 20 may also cover multiple light-emitting chips 18, and the light-emitting chips 18 are electrically connected in series and parallel.

Reference is made to FIG. 26, a plurality of light-emitting elements are formed by cutting along the outside of each encapsulating body 2, and then the temporary base 3 is removed.

Moreover, the light-emitting element according to still another aspect of the present invention is shown in FIG. 26. The light-emitting element includes two electrically conductive layers 11, a flexible insulating layer 12, a light-emitting chip 18, and an encapsulating body 10. A groove 110 is formed between the electrically conductive layers 11. The flexible insulating layer 12 is disposed within the groove 110 and links the electrically conductive layers 11, and an upper surface 120 of the flexible insulating layer 12 and an upper surface 112 of each electrically conductive layer 11 are at the same level. The light-emitting chip 18 is placed on one of the electrically conductive layers 11 or crossing over the flexible insulating layer 12. The light-emitting chip 18 is electrically connected to the electrically conductive layer 11 and covered by the encapsulating body 20. The encapsulating body 20 is preferably of hemisphere shape.

To sum up, in this embodiment, the flexible insulating layer 12 of the light-emitting element is disposed within the groove 100 formed between each two adjacent electrically conductive layers 11, therefore, the light-emitting element is not only flexible, but the height is reduced, and can be employed in compact lighting module.

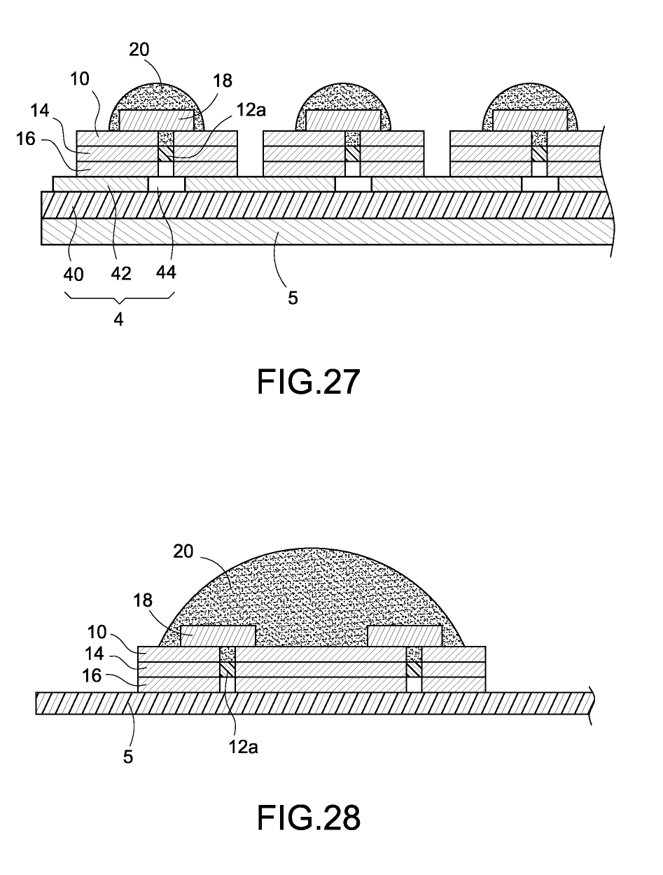

Reference is made to FIG. 27, a lighting module is composed of the light-emitting element mentioned above, a circuit board 4, and a heat-dissipating component 5. The plurality of light-emitting elements are placed on the circuit board 4. The circuit board 4 includes a base 10 and a metallic layer 42 disposed on the base 42. A particular circuit pattern is formed in the metallic layer 42. The light-emitting elements are electrically connected to the circuit board 4 (namely, the light-emitting elements and the metallic layer 42 are in electrically connection), therefore electric power conducted into the circuit drives the light-emitting element. The heat-dissipating component 5 is disposed under the circuit board 4 for rapidly conducted heat generated from the lighting light-emitting elements.

The light-emitting element may also be directly placed on a heat-dissipating component 5, such that a lighting module is composed of the light-emitting element and the heat-dissipating element, as shown in FIG. 28. The light-emitting element shown in FIG. 28 is the same as shown in FIG. 12. The heat-dissipating component is rapidly conducted heat generated from the light-emitting element.

Although the present invention has been described with reference to the foregoing preferred embodiment, it will be understood that the invention is not limited to the details thereof. Various equivalent variations and modifications can still occur to those skilled in this art in view of the teachings of the present invention. Thus, all such variations and equivalent modifications are also embraced within the scope of the invention as defined in the appended claims.

What is claimed is:

1. A light-emitting element comprising:
two electrically conductive layers, a groove formed between the electrically conductive layers;
a flexible insulating layer disposed within the groove and linking the electrically conductive layers;
a light-emitting chip placed on one of the electrically conductive layers or crossing over the flexible insulating layer; and
an encapsulating body covering the light-emitting chip.

2. The light-emitting element in claim 1, wherein an upper surface of the flexible insulating layer and an upper surface of each electrically conductive layer are at the same level.

3. The light-emitting element in claim 1, wherein a thickness of the flexible insulating layer is small than 200 micrometers.

4. The light-emitting element in claim 1, wherein a thickness of the electrically conductive layer is larger than 10 micrometers.

5. A light-emitting element comprising:
at least two first electrically conductive layers, a groove formed between the first electrically conductive layers;
a flexible insulating layer disposed under the groove and linking the first electrically conductive layers;
at least two second electrically conductive layers correspondingly disposed under the first electrically conductive layers, and a lower surface of each second conductive layer and a lower surface of the flexible insulating layer are at the same level;
at least one light-emitting chip electrically connected to the first conductive layers; and
an encapsulating body covering the light-emitting chip.

6. The light-emitting element in claim 5, wherein the light-emitting chip crosses over the flexible insulating layer, an electrode of the light-emitting chip is electrically connected to one of the first electrically conductive layer, and the other electrode of the light-emitting chip is electrically connected to the other first electrically conductive layer.

7. The light-emitting element in claim 6, wherein the encapsulating body at least partially disposed within the groove for tightly covering the light-emitting chip.

8. The light-emitting element in claim 5, further comprising at least one conductive wire crossing over the groove, the light-emitting chip is disposed on one of the first electrically conductive layers, one end of the conductive wire is connected to an electrode of the light-emitting chip, and the other end of the conductive wire is connected to the other electrode of the light-emitting chip.

9. The light-emitting element in claim 5, wherein a thickness of the flexible layer is smaller than 200 micrometers.

10. The light-emitting element in claim 5, wherein a thickness of each first electrically conductive layer is larger than 10 micrometers.

11. The light-emitting element in claim 5, wherein a width of the flexible insulating layer is equal to a width of the groove.

12. The light-emitting element in claim 5, wherein a width of the flexible insulating layer is larger than a width of the groove.

13. The light-emitting element in claim 12, wherein the width of the flexible insulating layer is uniform.

14. The light-emitting element in claim 12, wherein the width of the flexible insulating layer is progressively increased along a direction away from the first electrically conductive layers.

15. The light-emitting element in claim 12, wherein the width of the flexible insulating element is progressively decreased along a direction away from the first electrically conductive layers.

16. The light-emitting element in claim 5, further comprising at least two third electrically conductive layers correspondingly disposed under the second electrically conductive layers.

17. The light-emitting element in claim 5, further comprising an intermediary layer disposed under the second electrically conductive layers.

18. The light-emitting element in claim 17, further comprising at least two third electrically conductive layers disposed under the intermediary layer.

19. The light-emitting element in claim 5, further comprising a plurality of first electrically conductive layers and a plurality of light-emitting chips, the groove is formed between each two first electrically conductive layers, the flexible insulating layer is disposed under each groove and linking each two first electrically conductive layers, each light-emitting chip is disposed on one of the first electrically conductive layer of the two electrically conductive layers or crossing over the flexible insulating layer, the light-emitting chips is electrically connected in series and parallel via the first electrically conductive layers.

20. A manufacturing method for light-emitting element comprising:
a) providing a first electrically conductive layer and a flexible insulating layer, the flexible insulating layer disposed under the first electrically conductive layer;
b) forming at least one groove on the first electrically conductive layer;
c) removing partially flexible insulating layer so that the first electrically conductive layer is at least partially exposed out of the flexible insulating layer;
d) forming a second electrically conductive layer on the first electrically conductive layer exposed from the flexible insulating layer, and a lower surface of the second electrically conductive layer and a lower surface of the flexible insulating layer being at the same layer;
e) disposing at least one light-emitting chip on the electrically conductive layer or crossing over the flexible insulating layer; and
f) forming an encapsulating body covering the light-emitting chip.

21. The manufacturing method for light-emitting element in claim 20, further comprising:
forming an intermediary layer under the second electrically conductive layer.

22. The manufacturing method for manufacturing light-emitting element in claim 21, further comprising:
forming a third electrically conductive layer under the second electrically conductive layer or the intermediary layer.

23. A manufacturing method for light-emitting element comprising:
a) providing an electrically conductive layer;
b) forming at least one groove on the electrically conductive layer;
c) disposing a flexible insulating layer within the groove;
d) disposing at least one light-emitting chip on the electrically conductive layer or crossing over the flexible insulating layer, and
e) forming an encapsulating body covering the light-emitting chip.
